(19) United States
(12) Patent Application Publication
(10) Pub. No.: US 2006/0228490 A1
(43) Pub. Date: Oct. 12, 2006

(54) Gas distribution uniformity improvement by baffle plate with multi-size holes for large size PECVD systems

(75) Inventors: Qunhua Wang, San Jose, CA (US); Li Hou, Cupertino, CA (US); Sanjay D. Yadav, San Jose, CA (US); Gaku Furuta, Osaka (JP); Kenji Omori, Osaka (JP); Soo Young Choi, Fremont, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/101,305

(22) Filed: Apr. 7, 2005

(51) Int. Cl. C23F 1/00; B01J 19/08; C23C 16/00; H01L 21/306

(52) U.S. Cl. 427/457; 118/715; 156/345.34; 118/723 R

(57) ABSTRACT

Embodiments of a gas distribution plate for distributing gas in a processing chamber for large area substrates are provided. The embodiments describe a gas distribution plate assembly for a plasma processing chamber having a cover plate comprises a diffuser plate having an upstream side, a downstream side facing a processing region, and a plurality of gas passages formed through the diffuser plate, and a baffle plate, placed between the cover plate of the process chamber and the diffuser plate, having a plurality of holes extending from the upper surface to the lower surface of the baffle plate, wherein the plurality of holes have at least two sizes. The small pinholes of the baffle plate are used to allow sufficient pass-through of gas mixture, while the large holes of the baffle plate are used to improve the process uniformity across the substrate.

### BACKGROUND OF THE DISCLOSURE

1. Field of the Invention

Embodiments of the invention generally relate to a baffle plate used to improve film deposition uniformity in a deposition processing chamber.

2. Description of the Background Art

Liquid crystal displays or flat panels are commonly used for active matrix displays such as computer and television monitors. Plasma enhanced chemical vapor deposition (PECVD) is generally employed to deposit thin films on a substrate such as a transparent substrate for flat panel display or semiconductor wafer. PECVD is generally accomplished by introducing a precursor gas or gas mixture into a vacuum chamber that contains a substrate. The precursor gas or gas mixture is typically directed downwardly through a distribution plate situated near the top of the chamber. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate that is positioned on a temperature controlled substrate support. Volatile by-products produced during the reaction are pumped from the chamber through an exhaust system.

Flat panels processed by PECVD techniques are typically large, often exceeding 370 mm×470 mm. Large area substrates approaching and exceeding 4 square meters are envisioned in the near future. Gas distribution plates (or gas diffuser plates) utilized to provide uniform process gas flow over flat panels are relatively large in size, particularly as compared to gas distribution plates utilized for 200 mm and 300 mm semiconductor wafer processing.

FIG. 1 illustrates a cross-sectional schematic view of a thin film transistor structure. A common low temperature polysilicon TFT structure is the top gate TFT structure shown in FIG. 1. The substrate 101 may comprise a material that is essentially optically transparent in the visible spectrum, such as, for example, glass or clear plastic. The substrate may be of varying shapes or dimensions. Typically, for TFT applications, the substrate is a glass substrate with a surface area greater than about 500 mm². The substrate may have an underlayer 102 thereon. The underlayer 102 may be an insulating material, such as, for example, silicon dioxide (SiO₂) or silicon nitride (SiN). An n-type doped silicon layer 104n is deposited on the underlayer 102. Alternatively, the silicon layer may be a p-type doped layer. In one embodiment, the n-type doped silicon layer 104n is an amorphous silicon, which is melted and re-crystallized rapidly by an annealing process to form a polysilicon layer.

After the n-type doped silicon layer 104n is formed, selected portions thereof are ion implanted to form p-type doped regions 104p adjacent to n-type doped regions 104n. The interfaces between n-type regions 104n and p-type regions 104p are semiconductor junctions that support the ability of the thin film transistor to act as a switching device. By ion doping portions of semiconductor layer 104, one or more semiconductor junctions are formed, with an intrinsic electrical potential present across each junction.

A gate dielectric layer 108 is deposited on the n-type doped regions 104n and the p-type doped regions 104p. The gate dielectric layer 108 may comprise, for example, silicon dioxide (SiO₂), silicon nitride (SiN), or silicon oxynitride (SiON), deposited using an embodiment of a PECVD system in accordance with this invention. In one embodiment, the gate dielectric layer 103 is a silicon dioxide (SiO₂) layer, deposited using TEOS (tetraethylorthosilicate) and oxygen. TEOS is a liquid source precursor and can be vaporized to be carried into the process chamber. TEOS oxide film is known to have better comformality than silane oxide in the semiconductor industry.

A gate metal layer 110 is deposited on the gate dielectric layer 108. The gate metal layer 110 comprises an electrically conductive layer that controls the movement of charge carriers within the thin film transistor. The gate metal layer 110 may comprise a metal such as, for example, aluminum (Al), tungsten (W), chromium (Cr), tantalum (Ta), or combinations thereof, among others. The gate metal layer 110 may be formed using conventional deposition techniques. After deposition, the gate metal layer 110 is patterned to define gates using conventional lithography and etching techniques. After the gate metal layer 110 is formed, an interlayer dielectric 112 is formed thereon. The interlayer dielectric 112 may comprise, for example, an oxide such as silicon dioxide. Interlayer dielectric 112 may be formed using conventional deposition processes. The interlayer dielectric 112 is patterned to expose the n-type doped regions 104n. The patterned regions of the interlayer dielectric 112 are filled with a conductive material to form contacts 120. The contacts 120 may comprise a metal such as, for example, aluminum (Al), tungsten (W), molybdenum (Mo), chromium (Cr), tantalum (Ta), indium tin oxide (ITO), zinc oxide (ZnO) and combinations thereof, among others. The contacts 120 may be formed using conventional deposition techniques.

Thereafter, a passivation layer 122 may be formed thereon in order to protect and encapsulate a completed thin film transistor 125. The passivation layer 122 is generally an insulator and may comprise, for example, silicon oxide or silicon nitride. The passivation layer 122 may be formed using conventional deposition techniques. While FIG. 1 as well as the supporting discussion provide an embodiment in which the doped silicon layer 104 is an n-type silicon layer with p-type dopant ions implanted therein, one skilled in the art will recognize that forming this and other configurations are within the scope of the invention described below. For example, one may deposit a p-type silicon layer and implant n-type dopant ions in regions thereof. The TFT structure described here is merely used as an example.

FIG. 2A is a schematic cross-sectional view of one embodiment of a prior art plasma enhanced chemical vapor deposition system 200, available from AKT, a division of Applied Materials, Inc., Santa Clara, Calif. The system 200 generally includes a processing chamber 202 coupled to a gas source 204. The processing chamber 202 has walls 206 and a bottom 208 that partially define a process volume 212. The process volume 212 is typically accessed through a port (not shown) in the walls 206 that facilitates movement of a substrate 240 into and out of the processing chamber 202. The walls 206 and bottom 208 are typically fabricated from a unitary block of aluminum or other material compatible with processing. The walls 206 support a lid assembly 210 that contains a pumping plenum 214 that couples the process volume 212 to an exhaust port (that includes various pumping components, not shown).

A temperature controlled substrate support assembly 238 is centrally disposed within the processing chamber 202. The support assembly 238 supports a glass substrate 240 during processing. In one embodiment, the substrate support assembly 238 comprises an aluminum body 224 that encapsulates at least one embedded heater 232.

Generally, the support assembly 238 has a lower side 226 and an upper side 234. The upper side 234 supports the glass substrate 240. The lower side 226 has a stem 242 coupled thereto. The stem 242 couples the support assembly 238 to a lift system (not shown) that moves the support assembly 238 between an elevated processing position (as shown) and a lowered position that facilitates substrate transfer to and from the processing chamber 202. The stem 242 additionally provides a conduit for electrical and thermocouple leads between the support assembly 238 and other components of the system 200.

A bellows 246 is coupled between support assembly 238 (or the stem 242) and the bottom 208 of the processing chamber 202. The bellows 246 provides a vacuum seal between the chamber volume 212 and the atmosphere outside the processing chamber 202 while facilitating vertical movement of the support assembly 238.

The support assembly 238 generally is grounded such that RF power supplied by a power source 222 to a gas distribution plate assembly 218 positioned between the lid assembly 210 and substrate support assembly 238 (or other electrode positioned within or near the lid assembly of the chamber) may excite gases present in the process volume 212 between the support assembly 238 and the distribution plate assembly 218. The RF power from the power source 222 is generally selected commensurate with the size of the substrate to drive the chemical vapor deposition process. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate 240 that is positioned on a temperature controlled substrate support assembly 238.

The support assembly 238 additionally supports a circumscribing shadow frame 248. Generally, the shadow frame 248 prevents deposition at the edge of the glass substrate 240 and support assembly 238 so that the substrate does not stick to the support assembly 238. The support assembly 238 has a plurality of holes 228 disposed therethrough that accept a plurality of lift pins 250. The lift pins 250 are typically comprised of ceramic or anodized aluminum.

The lid assembly 210 provides an upper boundary to the process volume 212. The lid assembly 210 typically can be removed or opened to service the processing chamber 202. In one embodiment, the lid assembly 210 is fabricated from aluminum (Al). The lid assembly 210 includes a pumping plenum 214 formed therein coupled to an external pumping system (not shown). The pumping plenum 214 is utilized to channel gases and processing by-products uniformly from the process volume 212 and out of the processing chamber 202.

The lid assembly 210 typically includes an entry port 280 through which process gases provided by the gas source 204 are introduced into the processing chamber 202. The entry port 280 is also coupled to a cleaning source 282. The cleaning source 282 typically provides a cleaning agent, such as dissociated fluorine, that is introduced into the processing chamber 202 to remove deposition by-products and films from processing chamber hardware, including the gas distribution plate assembly 218.

The gas distribution plate assembly 218 is coupled to an interior side 220 of the lid assembly 210. The gas distribution plate assembly 218 is typically configured to substantially follow the profile of the glass substrate 240, for example, polygonal for large area flat panel substrates and circular for wafers. The gas distribution plate assembly 218 includes a perforated area 216 through which process and other gases supplied from the gas source 204 are delivered to the process volume 212. The perforated area 216 of the gas distribution plate assembly 218 is configured to provide uniform distribution of gases passing through the gas distribution plate assembly 218 into the processing volume 212.

The gas distribution plate assembly 218 typically includes a diffuser plate (or distribution plate) 258 suspended from a hanger plate 260. The diffuser plate 258 and hanger plate 260 may alternatively comprise a single unitary member. A plurality of gas passages 262 are formed through the diffuser plate 258 to allow a predetermined distribution of gas passing through the gas distribution plate assembly 218 and into the process volume 212. The hanger plate 260 maintains the diffuser plate 258 and the interior surface 220 of the lid assembly 210 in a spaced-apart relation, thus defining a plenum 264 therebetween. The plenum 264 allows gases flowing through the lid assembly 210 to uniformly distribute across the width of the diffuser plate 258 so that gas is provided uniformly above the center perforated area 216 and flows with a uniform distribution through the gas passages 262.

FIG. 2B is a partial sectional view of an exemplary diffuser plate 258 that is described in commonly assigned United States Patent Application Serial No. 10/824,347, titled “Gas Diffusion Shower Head Design For Large Area Plasma Enhanced Chemical Vapor Deposition”, filed on Apr. 14, 2004. For example, for a 696468 mm² (e.g. 762 mm×914 mm) diffuser plate, the diffuser plate 258 includes about 12,000 gas passages 262. For larger diffuser plates used to process larger flat panels, the number of gas passages 262 could be as high as 100,000. The gas passages 262 are generally patterned to promote uniform deposition of material on the substrate 240 positioned below the diffuser plate 258. Referring to FIG. 2B, in one embodiment, the gas passage 262 is comprised of a restrictive section 422, and a conical opening 406. The restrictive section 422 passes from the first side 418 of the diffuser plate 258 and is coupled to the conical opening 406. The conical opening 406 is coupled to the restrictive section 422 and flares radially outwards from the restrictive section 422 to the second side 420 of the diffuser plate 258. The second side 420 faces the surface of the substrate. The flaring angle 416 of the conical opening 406 is between about 20 to about 35 degrees.

The flared openings 406 promote plasma ionization of process gases flowing into the processing region 212. Moreover, the flared openings 406 provide larger surface area for hollow cathode effect to enhance plasma discharge. In one embodiment, the diameter of the restrictive section 422 is 1.40 mm (or 0.055 inch). The length of the restrictive section 422 is 14.35 mm (or 0.565 inch). The conical opening 406 has a diameter of 7.67 mm (or 0.302 inch) on the second side 420 of the diffuser plate 258. The flaring angle of the flared opening 406 is 22 degree. The length of the flared opening is 16.13 mm (or 0.635 inch).

As the size of substrate continues to grow in the TFT-LCD industry, especially, when the substrate size is at least about 100 cm by about 100 cm (or about 10,000 cm²), film thickness uniformity value of some films becomes too large to meet the stringent requirement of some device manufacturers for large area plasma-enhanced chemical vapor deposition (PECVD). For example, gate dielectric thickness uniformity requirement is below 2-3% for some manufacturers and could not be achieved by the existing designs of gas distribution plates.

Therefore, there is a need for an improved gas distribution plate assembly that improves the control of film properties, such as film thickness uniformity.

### SUMMARY OF THE INVENTION

Embodiments of a gas distribution plate for distributing gas in a processing chamber are provided. In one embodiment, a gas distribution plate assembly for a plasma processing chamber having a cover plate comprises a diffuser plate having an upstream side, a downstream side facing a processing region, and a plurality of gas passages formed through the diffuser plate, and a baffle plate, placed between the cover plate of the process chamber and the diffuser plate, having a plurality of holes extending from the upper surface to the lower surface of the baffle plate, wherein the plurality of holes have at least two sizes.

In another embodiment, a plasma processing chamber with a cover plate comprises a diffuser plate having an upstream side, a downstream side facing a processing region, and a plurality of gas passages formed through the diffuser plate, and a baffle plate, placed between the cover plate of the process chamber and the diffuser plate, having a plurality of holes extending from the upper surface to the lower surface of the baffle plate, wherein the plurality of holes have at least two sizes.

In another embodiment, a method of depositing a thin film on a substrate comprises placing a substrate in a process chamber having a cover and with a diffuser plate having an upstream side, a downstream side facing a processing region, and a plurality of gas passages formed through it, and a baffle plate, placed between the cover plate of the process chamber and the diffuser plate, having a plurality of holes extending from the upper surface to the lower surface of the baffle plate, wherein the plurality of holes have at least two sizes, flowing process gas(es) through the baffle plate and the diffuser plate toward a substrate supported on a substrate support, creating a plasma between the diffuser plate and the substrate support, and depositing a thin film on the substrate in the process chamber.

### BRIEF DESCRIPTION OF THE DRAWINGS

The teachings of the present invention can be readily understood by considering the following detailed description in conjunction with the accompanying drawings, in which:

FIG. 1 (Prior Art) depicts a cross-sectional schematic view of a bottom gate thin film transistor.

FIG. 2A (Prior Art) is a schematic cross-sectional view of an illustrative processing chamber having a gas diffuser plate.

FIG. 2B (Prior Art) depicts a cross-sectional schematic view of the gas diffuser plate of FIG. 2A.

FIG. 3A is a schematic cross-sectional view of an illustrative processing chamber having an exemplary gas diffuser plate and an exemplary baffle plate.

FIG. 3B depicts a cross-sectional schematic view of the exemplary baffle plate placed between a top plate and the exemplary diffuser plate.

FIG. 4 shows the process flow of depositing a thin film on a substrate in a process chamber with a diffuser plate.

FIG. 5A shows the tetraethylorthosilicate (TEOS) oxide deposition rate measurement across a 920 mm by 730 mm substrate collected from deposition with a gas distribution assembly without a baffle plate.

FIG. 5B shows the TEOS oxide deposition rate measurement across a 920 mm by 730 mm substrate collected from deposition with a gas distribution assembly with a baffle plate with small pinholes.

FIG. 5C shows a top view of a baffle plate with symmetrically distributed small pinholes.

FIG. 5D shows the TEOS oxide deposition rate measurement across a 920 mm by 730 mm substrate collected from deposition with a gas distribution assembly with a baffle plate with small pinholes and large holes.

FIG. 5E shows a top view of a baffle plate with symmetrically distributed large holes.

FIG. 6A shows the SiN deposition rate measurement across a 920 mm by 730 mm substrate collected from deposition with a gas distribution assembly without a baffle plate.

FIG. 6B shows the SiN deposition rate measurement across a 920 mm by 730 mm substrate collected from deposition with a gas distribution assembly with a baffle plate with small pinholes and large holes.

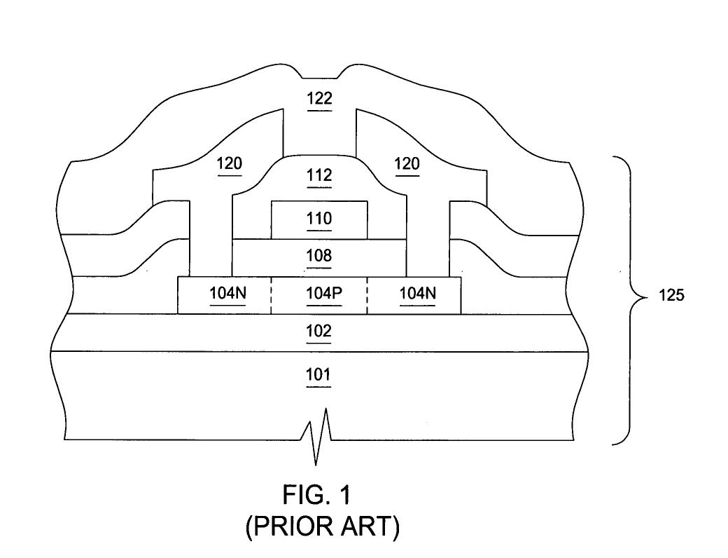

To facilitate understanding, identical reference numerals have been used, where possible, to designate identical elements that are common to the figures.

### DETAILED DESCRIPTION

The invention generally provides a gas distribution assembly for providing gas delivery within a processing chamber. The invention is illustratively described below in reference to a plasma enhanced chemical vapor deposition system configured to process large area substrates, such as a plasma enhanced chemical vapor deposition (PECVD) system, available from AKT, a division of Applied Materials, Inc., Santa Clara, Calif. However, it should be understood that the invention has utility in other system configurations such as etch systems, other chemical vapor deposition systems and any other system in which distributing gas within a process chamber is desired, including those systems configured to process round substrates.

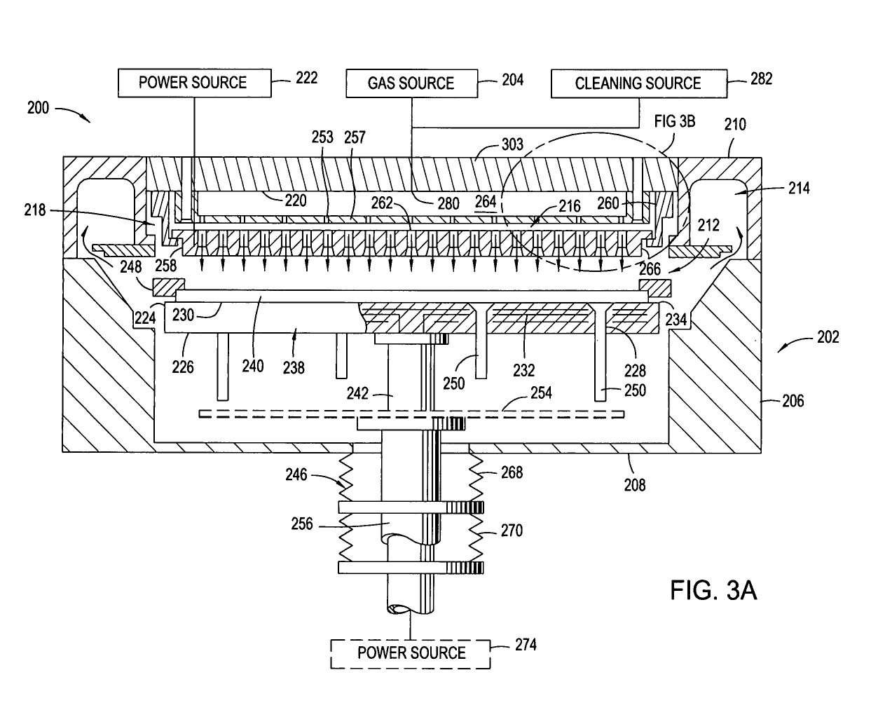

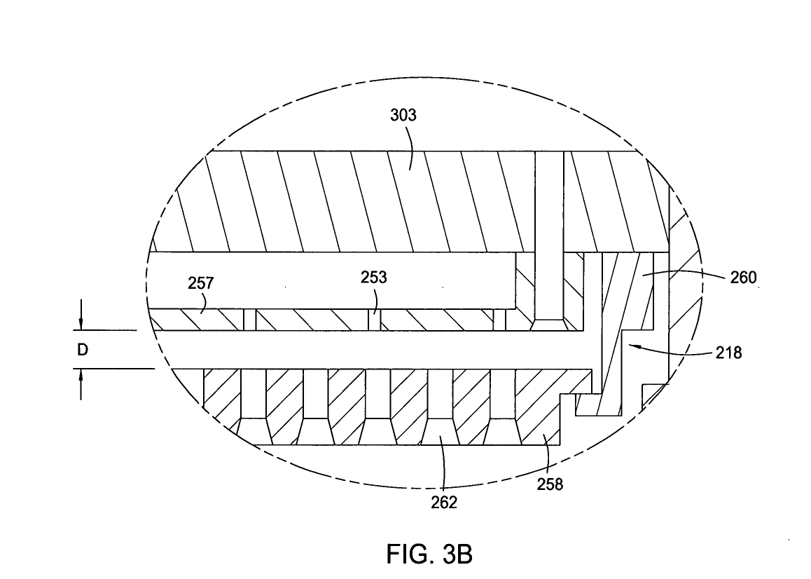

We have determined that the uniformity of reactive plasma distribution in the process chamber can be improved by adding a baffle plate 257 to the gas distribution plate assembly 218, as shown in FIG. 3A. The baffle plate 257 is placed between the cover plate 303 of the lid assembly 210 and the gas diffuser plate 258. The baffle plate 257 is typically configured to substantially follow the profile of the gas distribution plate 258, for example, polygonal for large area flat panel substrates and circular for wafers. The holes 253 across the baffle plate 257 and the gas passages 262 across the gas diffuser plate 258 together affect the gas distribution from the gas entry port 280. FIG. 3B is a drawing that shows the relationship between the cover plate 303, the baffle plate 257 and the diffuser plate 258. The baffle plate 257 is typically fabricated from stainless steel, aluminum (Al), anodized aluminum, nickel (Ni) or other RF conductive material. The baffle plate 257 could be cast, brazed, forged, hot iso-statically pressed or sintered. The baffle plate 257 is configured with a thickness that maintains sufficient flatness across the aperture 266 as not to adversely affect substrate processing. The baffle plate 257 also should be kept relatively thin to prevent excessive drilling time to make holes 253. In one embodiment, the thickness of the baffle plate 257 is between about 0.02 inch to about 0.20 inch. Since the baffle plate 257 works together with the gas diffuser plate 258 to affect the gas distribution uniformity, the distance “D” between the baffle plate 257 and the gas diffuser plate 258 should be kept small. In one embodiment, the distance “D” is below 0.6 inch. If the distance between the two plates is too large, the affect of the baffle plate 257 would diminish, since the gas or gas mixture would redistribute between the two plates.

The holes 253 across the baffle plate 257 have more than one size. The holes 253 should distribute symmetrically across the baffle plate to increase the gas distribution uniformity. The holes 253 are typically cylindrical; however, other shapes of holes can also be used. Different sizes of holes could be placed across the baffle plate 257 symmetrically to control the gas distribution uniformity. In one embodiment, the baffle plate 257 has holes 253 with at least two sets of sizes, small pinholes and large holes. The small pinholes are needed to transport high-flow-rate gas mixture from upstream to downstream without building up pressure in the blocker plate upstream plenum 264. Building up pressure in the blocker plate upstream plenum 264 could result in recombination of reactive radicals, such as the fluorine radicals from the remote plasma clean source. Large holes are used to adjust the film deposition thickness uniformity and profile across the substrate. These large holes alone are not enough for high gas flow, such as flow rate >3000 sccm, to pass through. For example during remote plasma clean (RPS) clean, the cleaning gas flow rate is about 4000 sccm. Sufficient numbers of small pinholes would prevent the pressure build up in the block plate upstream plenum 264. The small pinholes could be all at one size or at more than one size. In one embodiment, the diameters of the small pinholes are kept below 1.27 mm (or 0.05 inch). The large holes could also be at one size or at more than one size. In one embodiment, the diameters of these the large holes are between about 1.59 mm (or 1/16 inch) to about 6.35 mm (or ¼ inch).

The total cross-sectional areas of the small pinholes should be kept to larger than 1 inch² to ensure enough pass-through for the gas mixture, such as cleaning gas species generated by a RPS (remote plasma source) unit. In one embodiment, the diameters of the large holes are kept greater than 1.56 mm (or 1/16 inch).

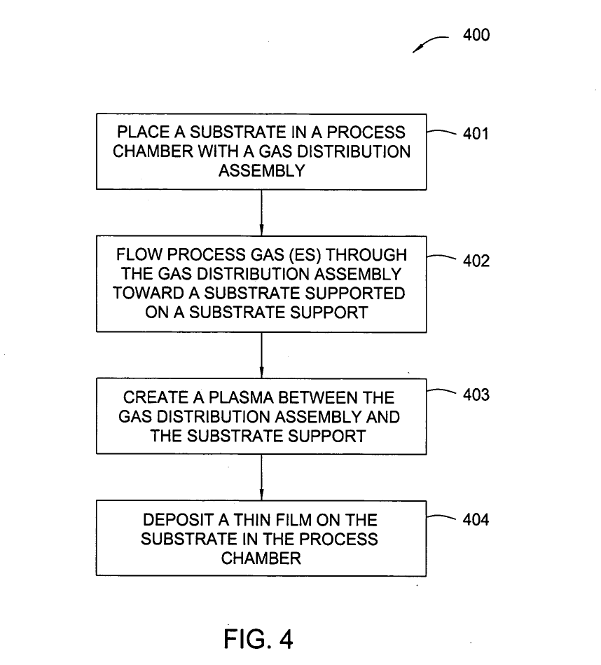

The process of depositing a thin film in a process chamber is shown in FIG. 4. The process starts at step 401 by placing a substrate in a process chamber with a gas distribution assembly. Next at step 402, flow process gas(es) through the gas distribution assembly toward a substrate supported on a substrate support. Then at step 403, create a plasma between the gas distribution assembly and the substrate support. At step 404, deposit a thin film on the substrate in the process chamber.

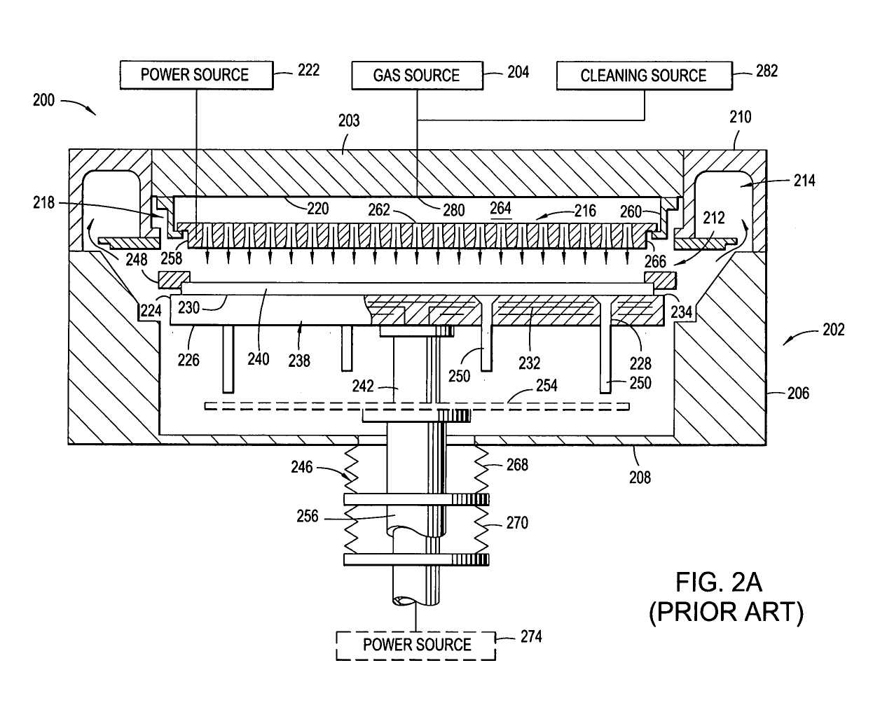

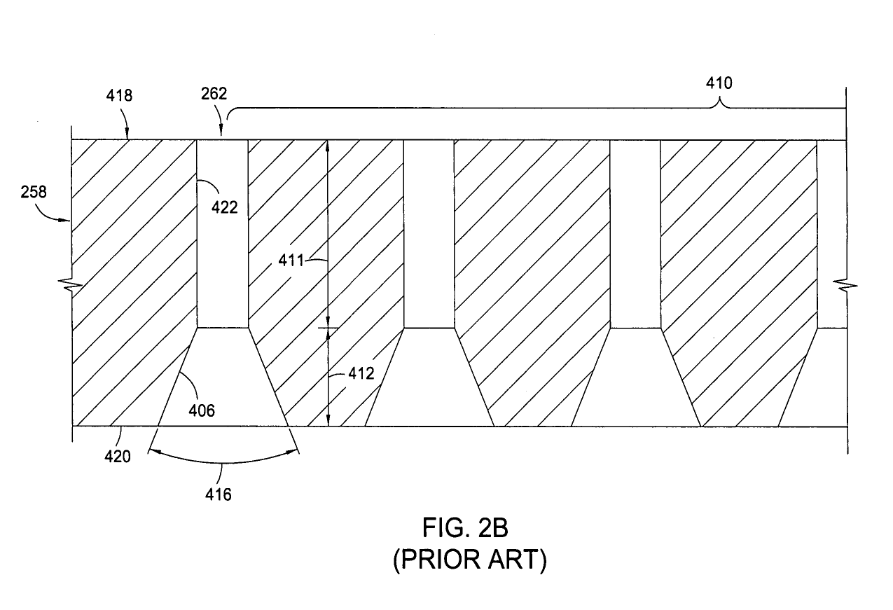

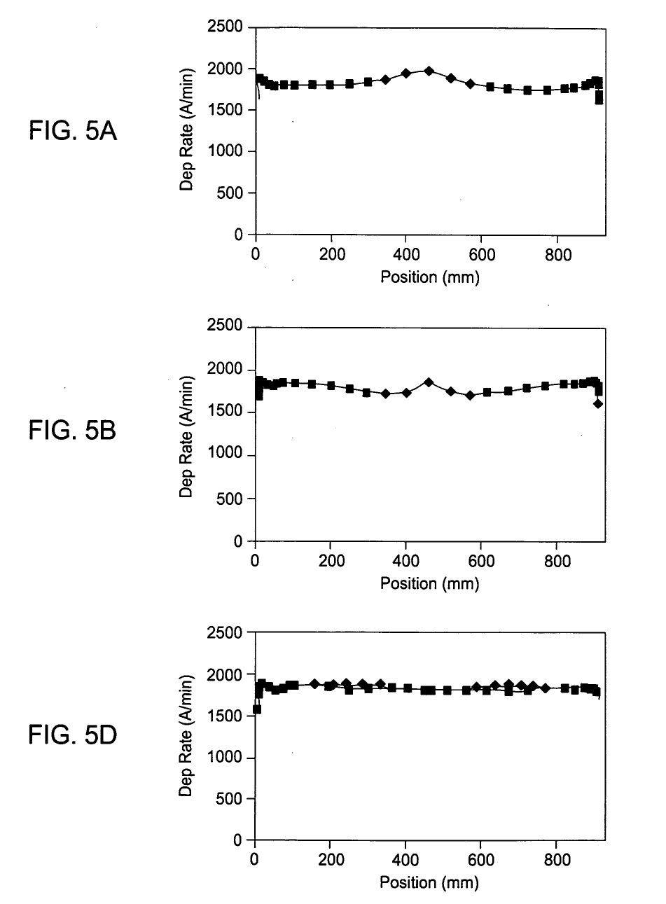

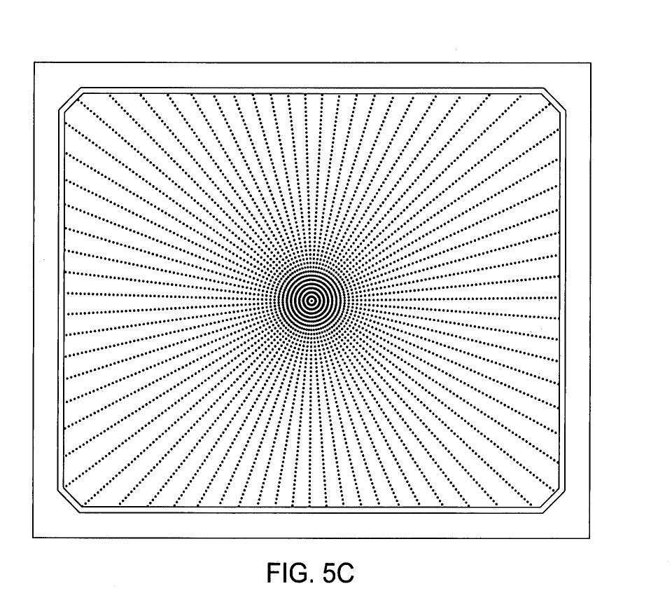

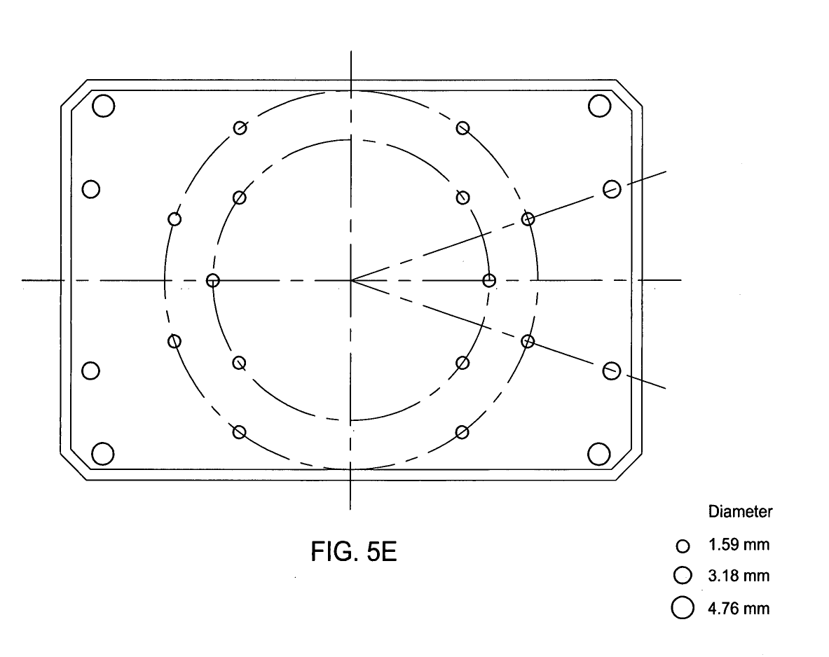

FIG. 5A shows a thickness profile of a TEOS oxide film across a glass substrate. The size of the substrate is 920 mm by 730 mm. The gas distribution assembly does not include a baffle plate. The diffuser plate has diffuser holes with design shown in FIG. 2B. The diameter of the restrictive section 422 is 1.40 mm (or 0.055 inch). The length of the restrictive section 422 is 14.35 mm (or 0.565 inch). The conical opening 406 has a diameter of 7.67 mm (or 0.302 inch) on the second side 420 of the diffuser plate 258. The flaring angle of the flared opening 406 is 22 degrees. The length of the flared opening is 16.13 mm (or 0.635 inch). The TEOS oxide film is deposited using 850 sccm TEOS, 300 sccm He, and 10000 sccm O₂, under 0.95 Torr, and 2700 watts source power. The spacing between the diffuser plate 258 and the substrate support assembly 238 is 11.94 mm (or 0.47 inch). The process temperature is maintained at about 400° C. The deposition rate is averaged to be 1800 Å/min and the thickness uniformity (with 15 mm edge exclusion) is about 5.5%, which is higher than the 2-3% manufacturing specification for some manufacturers. The thickness profile shows a center thick and edge thick profile, or “W shape” profile.

FIG. 5B shows a thickness profile of a TEOS oxide film across a glass substrate. The size of the substrate is 920 mm by 730 mm. The gas distribution assembly includes a baffle plate, in addition to the diffuser plate used for FIG. 5A deposition. The baffle plate only has small, cylindrical pinholes. The diameter of the small pinholes is 0.41 mm (or 0.016 inch). They are totally 8426 holes across the baffle plate. FIG. 5C shows the pattern of the pinholes on the baffle plate. The pinholes are radially and symmetrically distributed from the center of the blocker plate to the edges of the blocker plate. In one embodiment, the density of the pinholes near the center of the blocker plate is higher than the density of pinholes near the edges of the blocker plate.

The distance between the baffle plate and the diffuser plate is 12.55 mm (or 0.494 inch). The thickness of the baffle plate is 1.37 mm (or 0.054 inch). The diffuser plate is similar to the one used for FIG. 5A deposition. The spacing between the diffuser plate and the support assembly is 11.94 mm (or 0.47 inch). The deposition condition and process are the same as those of FIG. 5A. The deposition rate is found to average about 1800 Å/min and the thickness uniformity (with 15 mm edge exclusion) is about 5.0%, which is still higher than the manufacturing specification. The thickness profile still shows a center thick and edge thick profile, or “W shape” profile. The results show that a baffle plate with small pinholes only does not improve the TEOS uniformity.

FIG. 5D shows a thickness profile of a TEOS oxide film across a glass substrate. The size of the substrate is 920 mm by 730 mm. The gas distribution assembly includes a baffle plate. The baffle plate only has small, cylindrical pinholes, and large, cylindrical holes. The diameter of the small pinholes is 0.41 mm (or 0.016 inch). There are 8426 pinholes across the baffle plate. The size and location of the small pinholes are similar to the small pinholes on the baffle plate used for FIG. 5B deposition. FIG. 5C shows the pattern of the small pinholes on the baffle plate. The baffle plate also has large holes with diameters 1.59 mm (or 1/16 inch), 3.18 mm (or ⅛ inch), and 4.76 mm (or 3/16 inch). There are 14 holes with diameter of 1.59 mm, 4 holes with diameter of 3.18 mm and 4 holes with diameter of 4.76 mm. Their distribution across the baffle plate is shown in FIG. 5E. The distance between the baffle plate and the diffuser plate is 12.55 mm (or 0.494 inch). The thickness of the baffle plate is 1.37 mm (or 0.054 inch). The diffuser plate is similar to the one used for deposition in FIGS. 5A and 5B. The spacing between the diffuser plate and the support assembly is 11.94 mm (or 0.47 inch). The deposition condition and process are the same as those of FIG. 5A and FIG. 5B. The deposition rate is found to be averaged about 1800 Å/min and the thickness uniformity (with 15 mm edge exclusion) is about 1.8%, which is within the manufacturing specification. The thickness profile shows a smooth profile from center to edge. The results show that a baffle plate with small pinholes and large holes improve the TEOS uniformity.

The addition of the baffle plate does not appear to affect other TEOS oxide film properties. Table 1 compares stress, refractive index (RI), Si—O peak position, and wet etch rate.

TABLE 1
Comparison of film properties on substrates deposited with
TEOS Oxide film.

| | | Stress | Si—O | WER |
|---|---|---|---|---|
| Baffle Plate | RI | (E9Dynes/cm²) | Peak Position | (Å/min) |
| None | 1.46 | C0.7 | 1080 | 2043 |
| small pinholes | 1.46 | C0.8 | 1080 | 2058 |
| small pinholes + large | 1.46 | C0.6 | 1080 | 2093 |
| holes | | | | |

The refractive index (RI), film stress, Si—O peak position data and wet etch rate (WER) data all show similar values for three types of baffle plates. The Si—O peak position is measured by FTIR (Fourier Transform Infrared Spectroscopy). Wet etch rate is measured by immersing the samples in a BOE (buffered oxide etch) 6:1 solution.

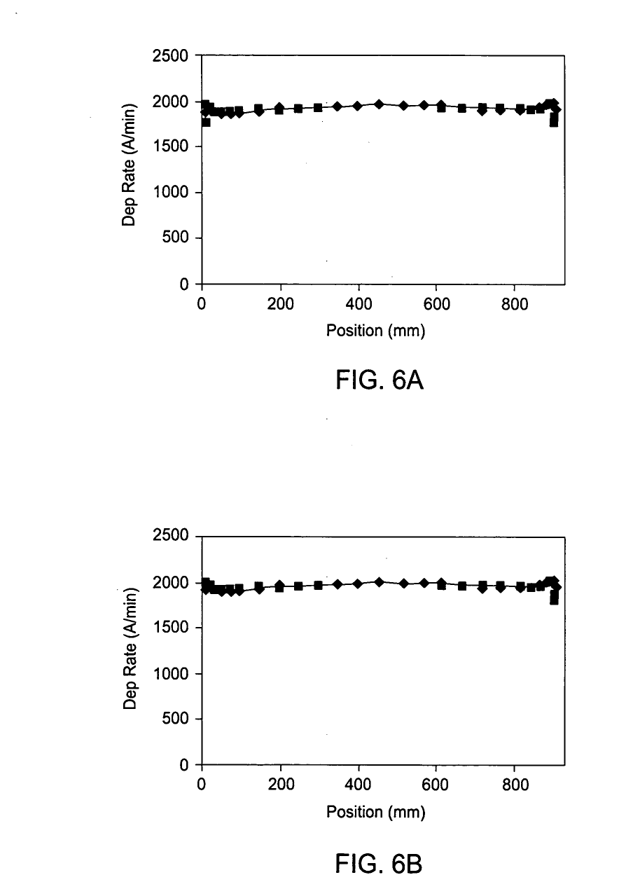

In addition to TEOS oxide film, the effect of the baffle plate on other types of dielectric film has also been investigated. FIG. 6A shows the SiN film deposition rate across the substrate surface, using a gas distribution assembly that is the same as the gas distribution assembly of FIG. 5A (without a baffle plate). The SiN film is deposited using 810 sccm SiH₄, 6875 sccm NH₃, and 9000 sccm N₂, under 1.60 Torr, and 3400 watts source power. The spacing between the diffuser plate and the support assembly is 28.83 mm (or 1.135 inch). The process temperature is maintained at about 400° C. The deposition rate is averaged to be about 1850 Å/min and the thickness uniformity (with 15 mm edge exclusion) is about 2.5%, which is within the manufacturing specification. The thickness profile shows a smooth profile from center to edge.

FIG. 6B shows the SiN film deposition rate across the substrate surface, using a gas distribution assembly that is the same as the gas distribution assembly of FIG. 5D (with a baffle plate with small pinholes and large holes). The SiN film is deposited using 810 sccm SiH₄, 6875 sccm NH₃, and 9000 sccm N₂, under 1.60 Torr, and 3400 watts source power. The spacing between the diffuser plate and the support assembly is 28.83 mm (or 1.135 inch). The process temperature is maintained at about 400° C. The deposition rate is averaged to be about 1850 Å/min and the thickness uniformity (with 15 mm edge exclusion) is about 2.5%, which is within the manufacturing specification. The thickness profile also shows a smooth profile from center to edge.

The results show that SiN film thickness across the substrate is not affected by the addition of a baffle plate with small pinholes and large holes such as the one used for depositing TEOS film in FIG. 5D and described in FIG. 5C and FIG. 5E. The addition of the baffle plate does not affect other SiN film properties. Table 2 compares stress, refractive index (RI), N—H/Si—H ratio, and wet etch rate.

TABLE 2
Comparison of film properties on substrates deposited with SiN film.

| | | Stress | | WER |
|---|---|---|---|---|
| Baffle Plate | RI | (E9Dynes/cm²) | N—H/Si—H | (Å/min) |
| None | 1.87 | T5.7 | 19.6/16.8 | 1878 |
| small pinholes + large | 1.87 | T5.3 | 19.7/16.3 | 1849 |
| holes | | | | |

The refractive index (RI), film stress, N—H/Si—H ratio data and wet etch rate (WER) data all show similar values for substrates deposited with or without a baffle plate with small pinholes and large holes as used in FIG. 5D deposition and described in FIG. 5C and FIG. 5E. The N—H/Si—H ratio is measured by FTIR. Wet etch rate is measured by immersing the samples in a BOE (buffered oxide etch) 6:1 solution.

The results show that using a baffle plate with small pinholes and large holes improves the TEOS oxide thickness uniformity and does not affect the other film properties of the TEOS film. The results also show that using the same baffle plate with small pinholes and large holes does not affect the film thickness uniformity and other film properties of SiN film. The difference could be due to the fact that TEOS is a liquid source and also has a higher molecular weight.

Gas distribution plates of gas distribution plate assembly that may be adapted to benefit from the invention described above are described in commonly assigned U.S. patent application Ser. No. 09/922,219, filed Aug. 8, 2001 by Keller et al., U.S. patent application Ser. No. 10/140,324, filed May 6, 2002 by Yim et al., and U.S. Ser. No. 10/337,483, filed Jan. 7, 2003 by Blonigan et al., U.S. Pat. No. 6,477,980, issued Nov. 12, 2002 to White et al., U.S. patent application Ser. No. 10/417,592, filed Apr. 16, 2003 by Choi et al., and U.S. patent application Ser. No. 10/823,347, filed on Apr. 12, 2004 by Choi et al., which are hereby incorporated by reference in their entireties.

Although the processes and examples used are for making thin film transistor devices, the concept of the invention can be used for making OLED application, solar panel substrates and other applicable devices.

Although several preferred embodiments which incorporate the teachings of the present invention have been shown and described in detail, those skilled in the art can readily devise many other varied embodiments that still incorporate these teachings.

1. A gas distribution plate assembly for a plasma processing chamber having a cover plate, comprising:
a diffuser plate having an upstream side, a downstream side facing a processing region, and a plurality of gas passages formed through the diffuser plate; and
a baffle plate, placed between the cover plate of the process chamber and the diffuser plate, having a plurality of holes extending from the upper surface to the lower surface of the baffle plate, wherein the plurality of holes have at least two sizes.

2. The gas distribution plate assembly of claim 1, wherein the thickness of the baffle plate is between about 0.02 inch to about 0.2 inch.

3. The gas distribution plate assembly of claim 1, wherein the distance between the baffle plate and the diffuser plate is below about 0.6 inch.

4. The gas distribution plate assembly of claim 1, wherein the plurality of holes of the baffle plate are cylindrical.

5. The gas distribution plate assembly of claim 4, wherein the smallest diameter of the plurality of cylindrical holes of the baffle plate is below about 0.05 inch and the total cross-sectional areas of the smallest diameter holes is greater than 1 inch².

6. The gas distribution plate assembly of claim 5, wherein the total cross-sectional areas of the smallest diameter holes is greater than 1 inch².

7. The gas distribution plate assembly of claim 6, wherein the plurality of cylindrical holes with smallest diameter is distributed symmetrically from the center of the blocker plate to the edge of the blocker plate.

8. The gas distribution plate assembly of claim 4, wherein the baffle plate has a plurality of cylindrical holes with diameters between about 1/16 inch to about ¼ inch and the diameters of these holes are greater than the smallest diameter of the plurality of cylindrical holes.

9. The gas distribution plate assembly of claim 8, wherein the number of the plurality of cylindrical holes with diameters greater than the smallest diameter of the plurality of cylindrical holes is at least 4.

10. The gas distribution plate assembly of claim 8, wherein the plurality of cylindrical holes with diameters greater than the smallest diameter of the plurality of cylindrical holes is distributed symmetrically across the baffle plate.

11. The gas distribution plate assembly of claim 1, wherein the plasma processing chamber is a plasma enhanced chemical vapor deposition chamber.

12. The gas distribution plate assembly of claim 1, wherein both the diffuser plate and the baffle plate are have a surface area that is greater than 370 mm×370 mm.

13. A plasma deposition processing chamber with a cover plate, comprising:
a diffuser plate having an upstream side, a downstream side facing a processing region, and a plurality of gas passages formed through the diffuser plate; and
a baffle plate, placed between the cover plate of the process chamber and the diffuser plate, having a plurality of cylindrical holes extending from the upper surface to the lower surface of the baffle plate, wherein the plurality of cylindrical holes have at least two sizes and are distributed symmetrically from the center the baffle plate to the edge of the baffle plate.

14. The plasma processing chamber of claim 13, wherein the space between the baffle plate and the diffuser plate is below about 0.6 inch.

15. The plasma processing chamber of claim 13, wherein the smallest diameter of the plurality of cylindrical holes of the baffle plate is below about 0.05 inch.

16. The plasma processing chamber of claim 15, wherein the cross-sectional areas of the smallest diameter holes is greater than 1 inch.

17. The plasma processing chamber of claim 16, wherein a plurality of cylindrical holes with diameters greater than the smallest diameter of the plurality of cylindrical holes are symmetrically distributed across the blocker plate.

18. The plasma processing chamber of claim 13, wherein both the diffuser plate and the baffle plate have a surface area that is greater than 370 mm×370 mm.

19. A method of depositing a thin film on a substrate, comprising:
placing a substrate in a process chamber having a cover and with a diffuser plate having an upstream side, a downstream side facing a processing region, and a plurality of gas passages formed through it, and a baffle plate, placed between the cover plate of the process chamber and the diffuser plate, having a plurality of holes extending from the upper surface to the lower surface of the baffle plate, wherein the plurality of holes have at least two sizes;
flowing process gas(es) through the baffle plate and the diffuser plate toward a substrate supported on a substrate support;
creating a plasma between the diffuser plate and the substrate support; and
depositing a thin film on the substrate in the process chamber.

20. The method of depositing a thin film on a substrate of claim 19, wherein the plurality of holes of the baffle plate are cylindrical.

21. The method of depositing a thin film on a substrate of claim 19, wherein the smallest diameter of the plurality of cylindrical holes of the baffle plate is below about 0.05 inch and the total cross-sectional areas of the smallest diameter holes is greater than 1 inch².

22. The method of depositing a thin film on a substrate of claim 21, wherein the plurality of cylindrical holes with smallest diameter is distributed symmetrically from center of the blocker plate to the edge of the blocker plate.

23. The method of depositing a thin film on a substrate of claim 25, wherein the uniformity of the thin film on the substrate is improved by the plurality of cylindrical holes with diameters greater than the smallest diameter of the plurality of cylindrical holes.

24. A method of depositing a thin film on a substrate, comprising:
placing a substrate in a process chamber having a cover and with a diffuser plate having an upstream side, a downstream side facing a processing region, and a plurality of gas passages formed through it, and a baffle plate, placed between the cover plate of the process chamber and the diffuser plate, having a plurality of holes extending from the upper surface to the lower surface of the baffle plate, wherein the plurality of holes have at least two sizes;
vaporizing a liquid precursor;
directing the vaporized precursor through the baffle plate and the diffuser plate toward a substrate supported on a substrate support;
creating a plasma between the diffuser plate and the substrate support; and
depositing a thin film on the substrate in the process chamber.

25. The method of claim 24, wherein the liquid precursor is TEOS.
